(19) United States
(12) Patent Application Publication
(10) Pub. No.: US 2026/0068263 A1
(43) Pub. Date: Mar. 5, 2026

(54) SEMICONDUCTOR DEVICE

(71) Applicant: Mitsubishi Electric Corporation, Tokyo (JP)

(72) Inventors: Kosuke SAKAGUCHI, Tokyo (JP); Kazuya KONISHI, Tokyo (JP); Ryosuke KOBAYASHI, Tokyo (JP); Kazuki NISHIDA, Tokyo (JP); Kakeru OTSUKA, Tokyo (JP)

(73) Assignee: Mitsubishi Electric Corporation, Tokyo (JP)

(21) Appl. No.: 19/261,597

(22) Filed: Jul. 7, 2025

(30) Foreign Application Priority Data
Aug. 30, 2024 (JP) 2024-148198

(51) Int. Cl. H10D 64/00; H10D 12/00; H10D 64/27

(52) U.S. Cl. CPC H10D 64/117; H10D 12/481; H10D 64/513; H10D 64/518

(57) ABSTRACT

A semiconductor device according to the present disclosure includes: a two-stage active dummy trench having a first upper electrode and a first lower electrode; and a two-stage active trench having a second upper electrode and a second lower electrode, wherein the first upper electrode, the second upper electrode, and the second lower electrode are connected to the same gate pad, the two-stage active dummy trench and the two-stage active trench extend in a horizontal direction in plan view, and a length of a region where the two-stage active dummy trench and the two-stage active trench are adjacent to each other is longer than a length of a region where the two-stage active dummy trench and the two-stage active trench are not adjacent to each other in the entire length of the two-stage active dummy trench and the two-stage active trench in the horizontal direction.

### BACKGROUND OF THE INVENTION

### Field of the Invention

The present disclosure relates to a semiconductor device whose conduction is controlled by a gate signal.

### Description of the Background Art

Conventionally, there is disclosed a semiconductor device including a two-stage active dummy trench, which has an upper electrode as a gate potential in an upper stage and a lower electrode as a potential other than the gate potential in a lower stage (see, for example, Japanese Patent Application Laid-Open No. 2019-12813, Japanese Patent Application Laid-Open No. 2022-145318, Japanese Patent Application Laid-Open No. 2021-184443, Japanese Patent Application Laid-Open No. 2021-150538, and Japanese Patent Application Laid-Open No. 2023-37881).

In a case where the semiconductor device is an insulated gate bipolar transistor (IGBT), Cgc/Cge, which is a gate capacitance ratio, can be greatly reduced to achieve low noise and low switching loss, but an N+ layer cannot be formed around the lower electrode in the two-stage active dummy trench. Therefore, since it is not possible to form a barrier of the N+ layer that accumulates holes, injected from a back surface side of the semiconductor, on a front surface side, and conductivity modulation cannot be promoted, there is a problem peculiar to the IGBT that an emitter-collector saturation voltage V_{CE} (sat) increases. Here, Cgc is a capacitance between a gate electrode and a collector electrode, and Cge is a capacitance between the gate electrode and an emitter electrode.

### SUMMARY

The present disclosure has been made to solve such a problem, and an object thereof is to provide a semiconductor device capable of suppressing an increase in an emitter-collector saturation voltage V_{CE} (sat) with low noise and low switching loss.

A semiconductor device according to the present disclosure includes: a semiconductor substrate having a drift layer of a first conductivity type between a first main surface and a second main surface; at least one two-stage active dummy trench having a first upper electrode as a gate potential in an upper stage and a first lower electrode as an emitter potential in a lower stage inside a trench provided on a side of the first main surface of the semiconductor substrate; at least one two-stage active trench having a second upper electrode as the gate potential in an upper stage and a second lower electrode as the gate potential in a lower stage inside a trench provided on the side of the first main surface of the semiconductor substrate; and a semiconductor layer of a second conductivity type provided on a side of the second main surface of the semiconductor substrate, wherein the first upper electrode, the second upper electrode, and the second lower electrode are connected to an identical gate pad, the two-stage active dummy trench and the two-stage active trench extend in a horizontal direction in plan view, and a length of a region where the two-stage active dummy trench and the two-stage active trench are adjacent to each other is longer than a length of a region where the two-stage active dummy trench and the two-stage active trench are not adjacent to each other in the entire length of the two-stage active dummy trench and the two-stage active trench in the horizontal direction.

According to the present disclosure, it is possible to suppress the increase in the emitter-collector saturation voltage V_{CE} (sat) with the low noise and the low switching loss.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a plan view of the semiconductor device according to the first preferred embodiment;

FIG. 3 is an enlarged view of a part of FIG. 2;

FIG. 4 is a cross-sectional view of a semiconductor device according to a first modification;

FIG. 5 is a cross-sectional view of a semiconductor device according to a second modification;

FIG. 6 is a cross-sectional view of a semiconductor device according to a sixth modification;

FIG. 7 is a cross-sectional view of a semiconductor device according to a seventh modification;

FIG. 8 is a cross-sectional view of a semiconductor device according to an eighth modification;

FIG. 9 is a cross-sectional view of a semiconductor device according to a ninth modification;

FIG. 10 is a cross-sectional view of a semiconductor device according to a tenth modification;

FIG. 11 is a cross-sectional view of a semiconductor device according to an eleventh modification;

FIG. 12 is a cross-sectional view of a semiconductor device according to a twelfth modification;

FIG. 13 is a cross-sectional view of a semiconductor device according to a thirteenth modification;

FIG. 14 is a cross-sectional view of a semiconductor device according to a fourteenth modification;

FIG. 15 is a cross-sectional view of a semiconductor device according to a fifteenth modification;

FIG. 16 is a cross-sectional view of a semiconductor device according to a eighteenth modification; and

FIG. 17 is a cross-sectional view of a semiconductor device according to a nineteenth modification.

### DESCRIPTION OF THE PREFERRED EMBODIMENTS

### First Preferred Embodiment

Hereinafter, a semiconductor device according to a first preferred embodiment will be described with reference to the drawings. The semiconductor device is an IGBT. Note that the same or corresponding components are denoted by the same reference signs, and repetition of the description may be omitted. In the following description, N and P represent conductivity types of a semiconductor. In the present disclosure, a first conductivity type is described as an N type, and a second conductivity type is described as a P type. These conductivity types may be reversed.

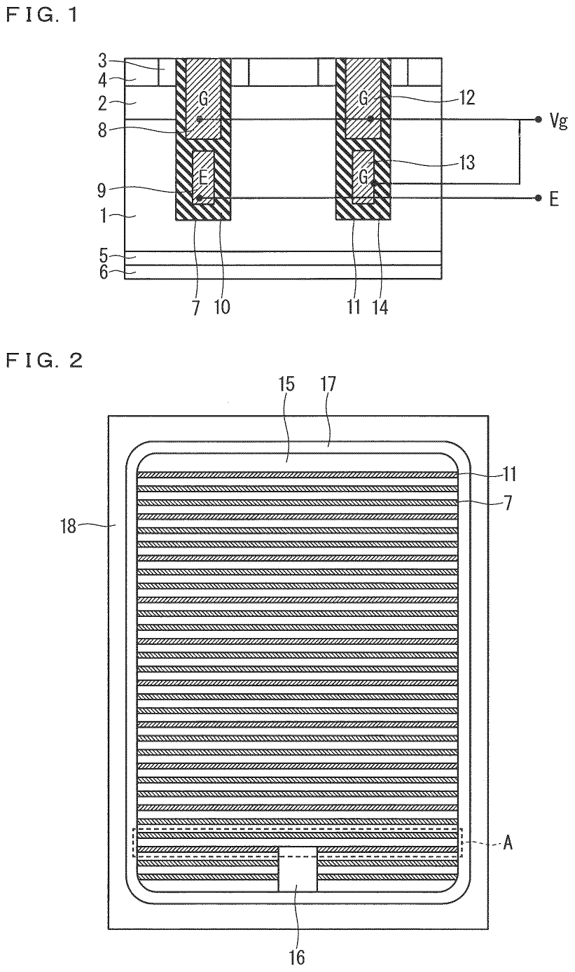

FIG. 1 is a cross-sectional view of the semiconductor device according to the first preferred embodiment. In FIG. 1, a semiconductor substrate ranges from an emitter layer 3 and a contact layer 4 to a collector layer 6. In FIG. 1, upper ends of the emitter layer 3 and the contact layer 4 are referred to as a first main surface of the semiconductor substrate, and a lower end of the collector layer 6 is referred to as a second main surface of the semiconductor substrate. The first main surface and the second main surface face each other.

As illustrated in FIG. 1, a base layer 2 of the P type is provided on the first main surface side of a drift layer 1 of the N-type. The emitter layer 3 of the N+ type and the contact layer 4 of the P+ type are provided on the first main surface side of the base layer 2.

The semiconductor substrate includes at least one two-stage active dummy trench 7 that penetrates the emitter layer 3 and the base layer 2 and reaches the drift layer 1. The two-stage active dummy trench 7 has a first upper electrode 8 as a gate potential in an upper stage and a first lower electrode 9 as an emitter potential in a lower stage inside a trench provided on the first main surface side of the semiconductor substrate.

The semiconductor substrate includes at least one two-stage active trench 11 that penetrates the emitter layer 3 and the base layer 2 and reaches the drift layer 1. The two-stage active trench 11 has a second upper electrode 12 as a gate potential in an upper stage and a second lower electrode 13 as a gate potential in a lower stage inside a trench provided on the first main surface side of the semiconductor substrate.

A buffer layer 5 of the N type having an N-type impurity concentration higher than that of the drift layer 1 is provided on the second main surface side of the drift layer 1. The collector layer 6 (semiconductor layer) of the P type is provided on the second main surface side of the buffer layer 5.

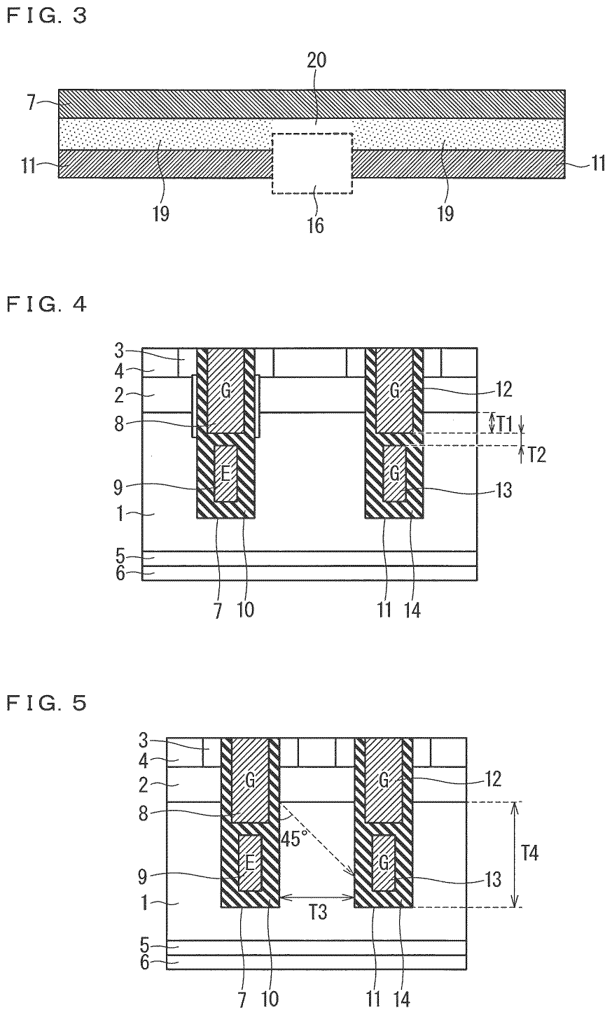

FIG. 2 is a plan view of the semiconductor device according to the first preferred embodiment. FIG. 3 is an enlarged view of a region A in FIG. 2.

As illustrated in FIG. 2, the two-stage active dummy trench 7 and the two-stage active trench 11 extend in the horizontal direction in an element region 15. Although FIG. 2 illustrates an example in which the two-stage active trench 11, the two-stage active dummy trench 7, and the two-stage active dummy trench 7 are arranged in this order in a direction perpendicular to the horizontal direction, the present disclosure is not limited thereto. The two-stage active dummy trench 7 and the two-stage active trench 11 may be appropriately arranged as necessary.

As illustrated in FIG. 3, in the entire length of the two-stage active dummy trench 7 and the two-stage active trench 11 (length between both ends of the two-stage active dummy trench 7 and the two-stage active trench 11) in the horizontal direction, lengths of regions 19 where the two-stage active dummy trench 7 and the two-stage active trench 11 are adjacent (the sum of lengths of the two adjacent regions 19 in the horizontal direction) is longer than a length of a region 20 where the two-stage active dummy trench 7 and the two-stage active trench 11 are not adjacent (the length of the non-adjacent region 20 in the horizontal direction).

A gate pad 16 is provided in the element region 15. The first upper electrode 8 of the two-stage active dummy trench 7 and the second upper electrode 12 and the second lower electrode 13 of the two-stage active trench 11 are connected to the gate pad 16.

A gate wiring region 17 is provided so as to surround the element region 15, and is connected to the gate pad 16. A termination region 18 is provided so as to surround the gate wiring region 17.

According to the first preferred embodiment, an N+ layer is formed around the second lower electrode 13 in the two-stage active trench 11. Therefore, it is possible to suppress an increase in an emitter-collector saturation voltage V_{CE} (sat) together with effects of low noise and low switching loss obtained by providing the two-stage active dummy trench 7.

In addition, it is possible to densely provide the regions 19 where the two-stage active dummy trench 7 and the two-stage active trench 11 are adjacent to each other by arranging the two-stage active dummy trench 7 and the two-stage active trench 11 in the horizontal direction. Therefore, it is possible to compensate for a disadvantage of a decrease in carrier accumulation in the two-stage active dummy trench 7 to the maximum.

### First Modification

FIG. 4 is a cross-sectional view of a semiconductor device according to a first modification. As illustrated in FIG. 4, in the two-stage active dummy trench 7, a first oxide film 10 has a first boundary oxide film located between the first upper electrode 8 and the first lower electrode 9. In the two-stage active trench 11, a second oxide film 14 has a second boundary oxide film located between the second upper electrode 12 and the second lower electrode 13.

A protrusion width T1 is a width between an end face of the base layer 2 on the second main surface side and an end face of the second upper electrode 12 on the second main surface side. The protrusion width T1 is longer than a film thickness T2 of the second boundary oxide film.

Although FIG. 4 illustrates the relationship between the protrusion width T1 in the two-stage active trench 11 and the film thickness T2 of the second boundary oxide film, the same applies to the two-stage active dummy trench 7. That is, a protrusion width, which is a width between the end face of the base layer 2 on the second main surface side and an end face of the first upper electrode 8 on the second main surface side, is longer than a film thickness of the first boundary oxide film.

According to the first modification, a carrier accumulation effect can be improved by increasing the protrusion width of each of the two-stage active dummy trench 7 and the two-stage active trench 11. In particular, the carrier accumulation effect can be improved by increasing the protrusion width of the two-stage active dummy trench 7.

In addition, as in the two-stage active trench 11 illustrated in FIG. 4, when a film thickness of a second lower oxide film covering the second lower electrode 13 is thicker than a film thickness of a second upper oxide film covering the second upper electrode 12 in the second oxide film 14, the increase in the emitter-collector saturation voltage V_{CE} (sat) can be suppressed by increasing the protrusion width T1 in the two-stage active trench 11. This is because a region where the second upper oxide film having a thinner film thickness protrudes increases so that the N+ layer is likely to be formed.

### Second Modification

FIG. 5 is a cross-sectional view of a semiconductor device according to a second modification. As illustrated in FIG. 5, in the semiconductor device according to the second modification, a length T3 between the two-stage active dummy trench 7 and the two-stage active trench 11 is shorter than a length T4 between an end face of the base layer 2 on the second main surface side and an end face of the two-stage active trench 11 on the second main surface side.

Although FIG. 5 illustrates the relationship between the length T3 between the two-stage active dummy trench 7 and the two-stage active trench 11 and the length T4 between the end face of the base layer 2 on the second main surface side and the end face of the two-stage active trench 11 on the second main surface side, the same applies to the two-stage active dummy trench 7. That is, the length T3 between the two-stage active dummy trench 7 and the two-stage active trench 11 is shorter than a length between the end face of the base layer 2 on the second main surface side and an end face of the two-stage active dummy trench 7 on the second main surface side.

According to the second modification, electrons diffused in a direction of 45° from a channel of the two-stage active dummy trench 7 reach the two-stage active trench 11, so that the carrier accumulation effect obtained by the two-stage active trench 11 can be improved.

### Third Modification

In a semiconductor device according to a third modification, the number of the two-stage active trenches 11 is the same as the number of the two-stage active dummy trenches 7.

According to the third modification, the carrier accumulation effect can be improved.

### Fourth Modification

In a semiconductor device according to a fourth modification, the number of the two-stage active trenches 11 is larger than the number of the two-stage active dummy trenches 7. For example, a ratio between the number of the two-stage active trenches 11 and the number of the two-stage active dummy trenches 7 is 6:4 or higher, and desirably 10:1 or lower.

According to the fourth modification, the carrier accumulation effect can be improved.

### Fifth Modification

In a semiconductor device according to a fifth modification, the number of the two-stage active trenches 11 is smaller than the number of the two-stage active dummy trenches 7. For example, a ratio between the number of the two-stage active trenches 11 and the number of the two-stage active dummy trenches 7 is 1:10 or higher, and 4:6 or lower.

According to the fifth modification, it is possible to achieve both reduction in switching loss and reduction in direct current (DC) loss by increasing the number of the two-stage active dummy trenches 7. Here, the DC loss refers to loss generated by resistance of a device when a current passes through the device.

### Sixth Modification

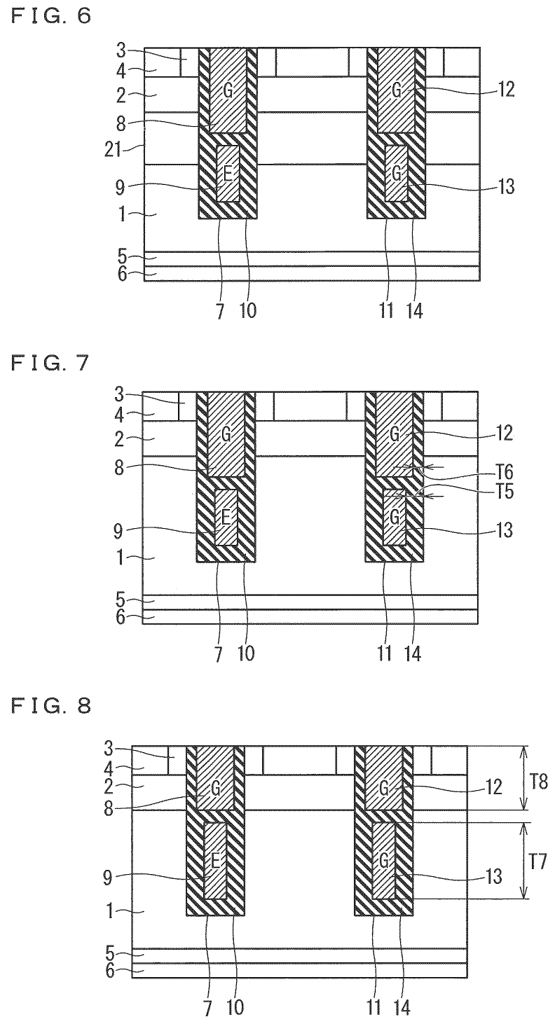

FIG. 6 is a cross-sectional view of a semiconductor device according to a sixth modification. As illustrated in FIG. 6, the semiconductor device according to the sixth modification further includes a carrier accumulation layer 21. The carrier accumulation layer 21 is provided on the first main surface side of the drift layer 1.

According to the sixth modification, the carrier accumulation effect can be improved by providing the carrier accumulation layer 21. In addition, the increase in the emitter-collector saturation voltage V_{CE} (sat) can be further suppressed as compared with the first preferred embodiment and the first to fifth modifications.

The carrier accumulation layer 21 in the sixth modification is also applicable to the first preferred embodiment and other modifications.

### Seventh Modification

FIG. 7 is a cross-sectional view of a semiconductor device according to a seventh modification. As illustrated in FIG. 7, in the two-stage active dummy trench 7, the first oxide film 10 has a first upper oxide film covering the first upper electrode 8 and a first lower oxide film covering the first lower electrode 9. In the two-stage active trench 11, the second oxide film 14 includes the second upper oxide film covering the second upper electrode 12 and the second lower oxide film covering the second lower electrode 13.

In the two-stage active trench 11, a film thickness T5 of the second lower oxide film is thicker than a film thickness T6 of the second upper oxide film.

Although FIG. 7 illustrates the relationship between the film thickness T5 of the second lower oxide film and the film thickness T6 of the second upper oxide film, the same applies to the two-stage active dummy trench 7. That is, a film thickness of the first lower oxide film is thicker than a film thickness of the first upper oxide film.

According to the seventh modification, an increase in switching loss due to an increase in Cgc can be suppressed by increasing the film thickness of the second lower oxide film of the two-stage active trench 11.

In addition, since the film thickness of the first lower oxide film is made thicker than the film thickness of the first upper oxide film, insulation between the first upper electrode 8 and the first lower electrode 9 is enhanced, and gate reliability such as time dependent dielectric breakdown (TDDB) is improved. The same effects can be obtained by making the film thickness of the second lower oxide film thicker than the film thickness of the second upper oxide film.

### Eighth Modification

FIG. 8 is a cross-sectional view of a semiconductor device according to an eighth modification. As illustrated in FIG. 8, in the two-stage active trench 11, a length T7 of the second lower electrode 13 in a depth direction is longer than a length T8 of the second upper electrode 12 in the depth direction. As a result, a region of the second upper electrode 12 covered with the second upper oxide film having a thinner film thickness is narrowed.

In the two-stage active dummy trench 7, a length of the first lower electrode 9 in the depth direction is longer than a length of the first upper electrode 8 in the depth direction. As a result, a Cgc connection region of the first upper electrode 8 is narrowed.

According to the eighth modification, it is possible to suppress the increase in the switching loss due to the increase in Cgc.

### Ninth Modification

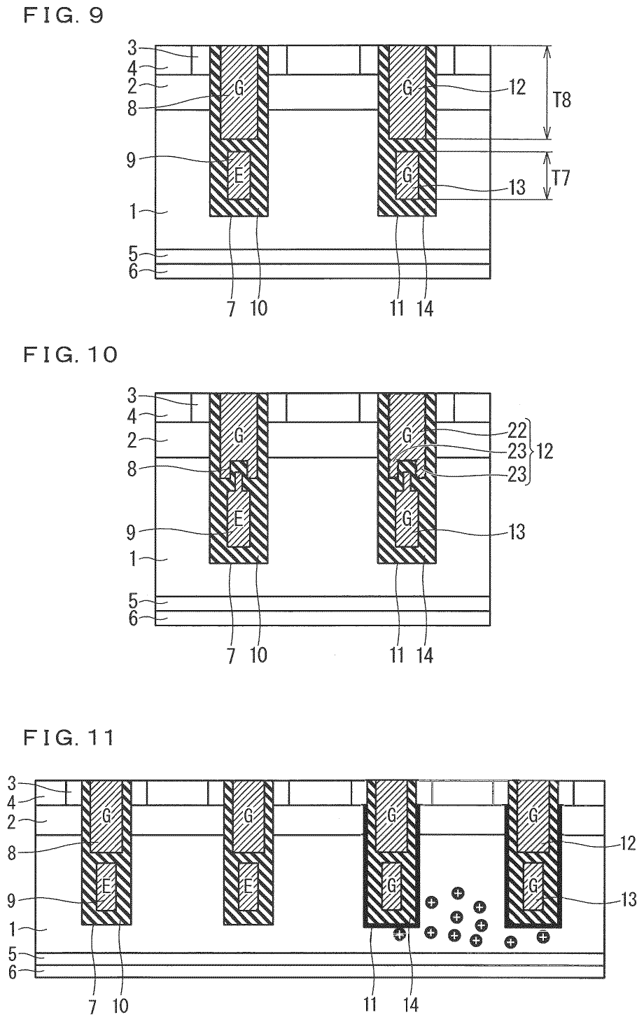

FIG. 9 is a cross-sectional view of a semiconductor device according to a ninth modification. As illustrated in FIG. 9, in the two-stage active trench 11, the length T7 of the second lower electrode 13 in the depth direction is shorter than the length T8 of the second upper electrode 12 in the depth direction. In the two-stage active dummy trench 7, the length of the first lower electrode 9 in the depth direction is shorter than the length of the first upper electrode 8 in the depth direction.

According to the ninth modification, the N+ layer is deepened by increasing the length in the depth direction of the first upper electrode 8 of the two-stage active dummy trench 7. In a case where the second upper oxide film is thin as illustrated in FIG. 9, a region where the second upper oxide film is thin (a region where the N+ layer is likely to be formed) in the two-stage active trench 11 is also deepened. Therefore, the increase in the emitter-collector saturation voltage V_{CE} (sat) can be further suppressed as compared with the first preferred embodiment and the first to eighth modifications.

### Tenth Modification

FIG. 10 is a cross-sectional view of a semiconductor device according to a tenth modification. As illustrated in FIG. 10, in the two-stage active trench 11, the second upper electrode 12 has a first portion 22 and a second portion 23 forming a shape recessed toward the first main surface. The second portion 23 is formed so as to project from a face of the first portion on the second main surface side. The second lower electrode 13 has a projection forming a shape projecting toward the first main surface side.

Also in the two-stage active dummy trench 7, the first upper electrode 8 similarly has a first portion and a second portion forming a shape recessed toward the first main surface. The first lower electrode 9 has a projection forming a shape projecting toward the first main surface side.

According to the tenth modification, the N+ layer is also formed around the second portion in addition to the first portion. Therefore, the N+ layer formed in the two-stage active dummy trench 7 is deepened. In a case where the second upper oxide film is thin as illustrated in FIG. 10, the region where the second upper oxide film is thin (the region where the N+ layer is likely to be formed) in the two-stage active trench 11 is also deepened. Therefore, the increase in the emitter-collector saturation voltage V_{CE} (sat) can be further suppressed as compared with the first preferred embodiment and the first to ninth modifications.

### Eleventh Modification

FIG. 11 is a cross-sectional view of a semiconductor device according to an eleventh modification. As illustrated in FIG. 11, in the semiconductor device according to the eleventh modification, two or more two-stage active dummy trenches 7 are provided adjacent to each other, and two or more two-stage active trenches 11 are provided adjacent to each other. Note that the number of the two-stage active dummy trenches 7 and the number of the two-stage active trenches 11 are two in the example of FIG. 11, but may be three or more.

In the two-stage active trench 11, the N+ layer is formed around the second lower electrode 13. Therefore, since the two-stage active trenches 11 are provided adjacent to each other, the carrier accumulation effect can be improved, and the increase in the emitter-collector saturation voltage V_{CE} (sat) can be further suppressed as compared with the first preferred embodiment and the first to fifth modifications.

### Twelfth Modification

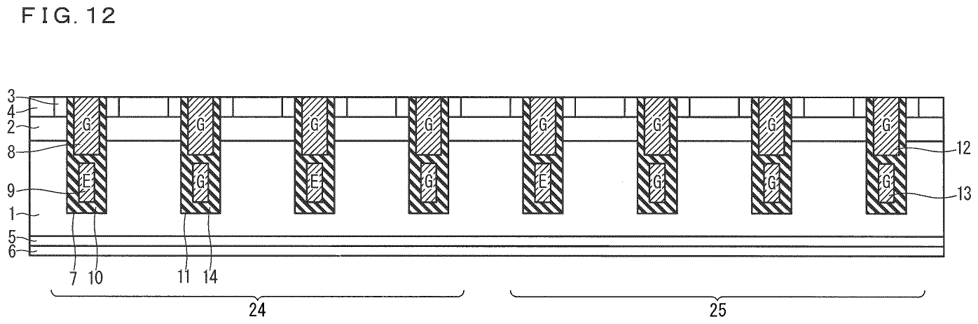

FIG. 12 is a cross-sectional view of a semiconductor device according to a twelfth modification. As illustrated in FIG. 12, the semiconductor device according to the twelfth modification includes a first trench group 24 and a second trench group 25 each including the two-stage active dummy trench 7 and the two-stage active trench 11.

The first trench group 24 includes two two-stage active dummy trenches 7 and two two-stage active trenches 11, and the ratio including the two-stage active trench 11 is 0.5. In addition, the second trench group 25 includes one two-stage active dummy trench 7 and three two-stage active trenches 11, and the ratio including the two-stage active trench 11 is 0.75. In this manner, the ratio including the two-stage active trench 11 is different between the first trench group 24 and the second trench group 25.

Although a case where each of the first trench group 24 and the second trench group 25 includes four trenches is illustrated in the example of FIG. 12, the present disclosure is not limited thereto. In addition, the ratio including the two-stage active trench 11 in each of the first trench group 24 and the second trench group 25 is not limited to the example of FIG. 12.

According to the twelfth modification, it is possible to provide regions having different emitter-collector saturation voltages V_{CE} (sat) in the semiconductor device in plan view, and the optimal number of the two-stage active trenches 11 can be provided. For example, the ratio including the two-stage active trench 11 is made higher in a trench group provided in a chip central portion (the central portion of the semiconductor device in plan view) where heat is likely to accumulate, and the ratio including the two-stage active trench 11 is made lower in a trench group provided in a chip outer peripheral portion (the outer peripheral portion of the semiconductor device in plan view) where heat is likely to escape. As a result, it is possible to achieve both the effect of reducing the switching loss by the two-stage active dummy trench 7 and the effect of reducing the emitter-collector saturation voltage V_{CE} (sat) by the two-stage active trench 11.

### Thirteenth Modification

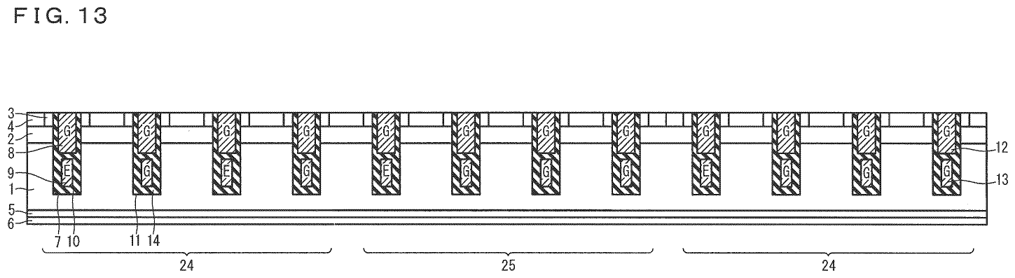

FIG. 13 is a cross-sectional view of a semiconductor device according to a thirteenth modification. As illustrated in FIG. 13, in the semiconductor device according to the thirteenth modification, the second trench group 25 is provided in the central portion, and the first trench group 24 is provided in the outer peripheral portion. The ratio including the two-stage active trench 11 is 0.75 in the second trench group 25, and the ratio including the two-stage active trench 11 in the first trench group 24 is 0.5. That is, the ratio the two-stage active trenches 11 in the second trench group 25 provided in the central portion is higher than the ratio including the two-stage active trench 11 in the first trench group 24 provided in the outer peripheral portion.

In a case where the semiconductor device operates at a low frequency, the switching loss is small since the number of times of switching of the semiconductor device is small. In such a semiconductor device, it is effective to emphasize the DC loss rather than the switching loss. According to the thirteenth modification, the DC loss can be reduced since the ratio including the two-stage active trench 11 in the second trench group 25 provided in the central portion is made higher than the ratio including the two-stage active trench 11 in the first trench group 24 provided in the outer peripheral portion.

### Fourteenth Modification

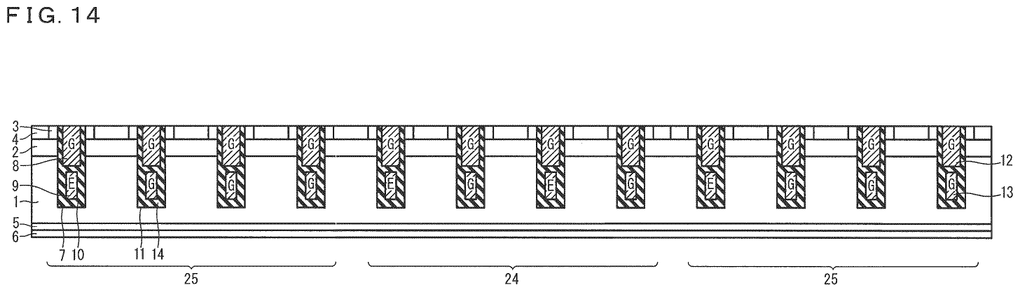

FIG. 14 is a cross-sectional view of a semiconductor device according to a fourteenth modification. As illustrated in FIG. 14, in the semiconductor device according to the fourteenth modification, the first trench group 24 is provided in the central portion, and the second trench group 25 is provided in the outer peripheral portion. The ratio including the two-stage active dummy trench 7 in the first trench group 24 is 0.5, and the ratio including the two-stage active dummy trench 7 in the second trench group 25 is 0.25. That is, the ratio including the two-stage active dummy trench 7 in the first trench group 24 provided in the central portion is higher than the ratio including the two-stage active dummy trench 7 in the second trench group 25 provided in the outer peripheral portion.

In a case where the semiconductor device operates at a high frequency, the switching loss is large since the number of times of switching of the semiconductor device is large. In such a semiconductor device, it is effective to emphasize the switching loss. According to the fourteenth modification, the switching loss can be reduced since the ratio including the two-stage active dummy trench 7 in the first trench group 24 provided in the central portion is made higher than the ratio including the two-stage active dummy trench 7 in the second trench group 25 provided in the outer peripheral portion.

### Fifteenth Modification

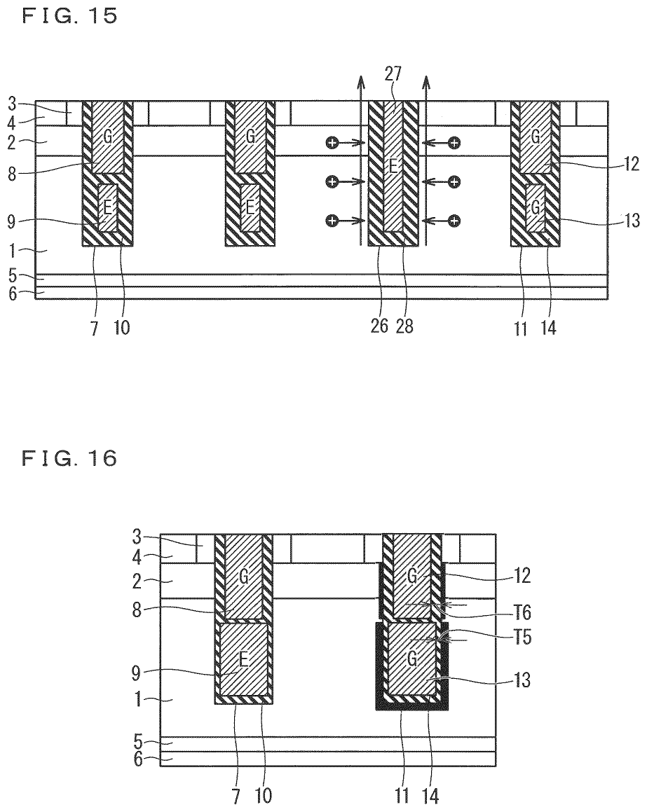

FIG. 15 is a cross-sectional view of a semiconductor device according to a fifteenth modification. As illustrated in FIG. 15, the semiconductor device according to the fifteenth modification further includes a one-stage dummy trench 26.

Specifically, the one-stage dummy trench 26 that penetrates the emitter layer 3 and the base layer 2 and reaches the drift layer 1 is provided in the semiconductor substrate. The one-stage dummy trench 26 includes a dummy electrode 27 and a dummy oxide film 28 covering the dummy electrode 27 inside a trench provided on the first main surface side of the semiconductor substrate. The dummy electrode 27 is an emitter potential.

According to the fifteenth modification, since holes are attracted to the dummy electrode 27 which is the emitter potential, the density of holes at an interface of the one-stage dummy trench 26 increases. As a result, the holes are likely to be discharged to an emitter electrode, so that turn-off loss can be reduced.

### Sixteenth Modification

In a semiconductor device according to a sixteenth modification, the number of the one-stage dummy trenches 26 is smaller than the number of the two-stage active dummy trenches 7.

According to the sixteenth modification, it is possible to suppress the increase in the emitter-collector saturation voltage V_{CE} (sat) due to an increase in hole extraction effect by reducing the number of the one-stage dummy trenches 26.

### Seventeenth Modification

In a semiconductor device according to a seventeenth modification, the number of the one-stage dummy trenches 26 is smaller than the number of the two-stage active trenches 11.

According to the seventeenth modification, it is possible to suppress the increase in the emitter-collector saturation voltage V_{CE} (sat) due to the increase in the hole extraction effect by reducing the number of the one-stage dummy trenches 26.

### Eighteenth Modification

FIG. 16 is a cross-sectional view of a semiconductor device according to an eighteenth modification. As illustrated in FIG. 16, in the two-stage active trench 11, the film thickness T5 of the second lower oxide film is thinner than the film thickness T6 of the second upper oxide film.

Although FIG. 16 illustrates the relationship between the film thickness T5 of the second lower oxide film and the film thickness T6 of the second upper oxide film, the same applies to the two-stage active dummy trench 7. That is, the film thickness of the first lower oxide film is thinner than the film thickness of the first upper oxide film.

According to the eighteenth modification, since the film thickness of the second lower oxide film of the two-stage active trench 11 is made thin, the N+ layer formed around the second lower electrode 13 in the two-stage active trench 11 can be made thick, and an impurity concentration of the N+ layer can be increased. Therefore, the increase in the emitter-collector saturation voltage V_{CE} (sat) can be further suppressed as compared with the first preferred embodiment and the first to seventeenth modifications.

### Nineteenth Modification

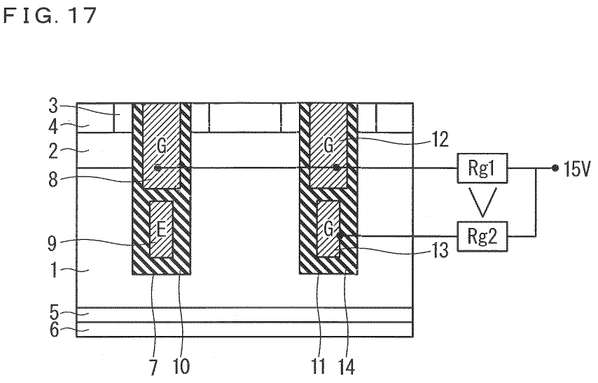

FIG. 17 is a cross-sectional view of a semiconductor device according to a nineteenth modification. As illustrated in FIG. 17, the semiconductor device according to the nineteenth modification includes a first resistor Rg1 and a second resistor Rg2.

The first resistor Rg1 is connected between the first upper electrode 8 and the second upper electrode 12, and a gate electrode (not illustrated). The second resistor Rg2 is connected between the second lower electrode 13 and the gate electrode. A resistance value of the first resistor Rg1 is larger than a resistance value of the second resistor Rg2.

According to the nineteenth modification, since the resistance value of the first resistor Rg1 is made larger than the resistance value of the second resistor Rg2, a charge speed with respect to the second lower electrode 13 increases, so that the N+ layer formed around the second lower electrode 13 can be made thick, and the impurity concentration of the N+ layer can be increased. Therefore, the increase in the emitter-collector saturation voltage V_{CE} (sat) can be further suppressed as compared with the first preferred embodiment and the first to seventeenth modifications.

### Twentieth Modification

A semiconductor device according to a twentieth modification is a reverse conducting-insulated gate bipolar transistor (RC-IGBT).

Specifically, the semiconductor device according to the twentieth modification includes an IGBT region and a diode region. For example, the two-stage active trench 11 may be provided in the IGBT region, and the two-stage active dummy trench 7 may be provided in the diode region.

Note that the preferred embodiment can be appropriately modified or omitted within the scope of the present disclosure.

### Appendixes

Hereinafter, various aspects of the present disclosure will be collectively described as appendixes.

### (Appendix 1)

A semiconductor device comprising:

a semiconductor substrate having a drift layer of a first conductivity type between a first main surface and a second main surface;

at least one two-stage active dummy trench having a first upper electrode as a gate potential in an upper stage and a first lower electrode as an emitter potential in a lower stage inside a trench provided on a side of the first main surface of the semiconductor substrate;

at least one two-stage active trench having a second upper electrode as the gate potential in an upper stage and a second lower electrode as the gate potential in a lower stage inside a trench provided on the side of the first main surface of the semiconductor substrate; and

a semiconductor layer of a second conductivity type provided on a side of the second main surface of the semiconductor substrate, wherein

the first upper electrode, the second upper electrode, and the second lower electrode are connected to an identical gate pad,

the two-stage active dummy trench and the two-stage active trench extend in a horizontal direction in plan view, and

a length of a region where the two-stage active dummy trench and the two-stage active trench are adjacent to each other is longer than a length of a region where the two-stage active dummy trench and the two-stage active trench are not adjacent to each other in an entire length of the two-stage active dummy trench and the two-stage active trench in the horizontal direction.

### (Appendix 2)

The semiconductor device according to Appendix 1, further comprising a base layer of the second conductivity type provided on the side of the first main surface of the semiconductor substrate, wherein

the two-stage active dummy trench has a first boundary oxide film located between the first upper electrode and the first lower electrode,

the two-stage active trench has a second boundary oxide film located between the second upper electrode and the second lower electrode, and

a protrusion width, which is a width between an end face of the base layer on the side of the second main surface and an end face of each of the first upper electrode and the second upper electrode on the side of the second main surface is longer than a film thickness of the first boundary oxide film and a film thickness of the second boundary oxide film.

### (Appendix 3)

The semiconductor device according to Appendix 1 or 2, further comprising a base layer of the second conductivity type provided on the side of the first main surface of the semiconductor substrate, wherein

a length between the two-stage active dummy trench and the two-stage active trench is shorter than a length between an end face of the base layer on the side of the second main surface and each of an end face of the two-stage active dummy trench on the side of the second main surface and an end face of the two-stage active trench on the side of the second main surface.

### (Appendix 4)

The semiconductor device according to any one of Appendixes 1 to 3, wherein a number of the two-stage active trenches is identical to a number of the two-stage active dummy trench.

### (Appendix 5)

The semiconductor device according to any one of Appendixes 1 to 3, wherein a number of the two-stage active trenches is larger than a number of the two-stage active dummy trench.

### (Appendix 6)

The semiconductor device according to any one of Appendixes 1 to 3, wherein a number of the two-stage active trenches is smaller than a number of the two-stage active dummy trench.

### (Appendix 7)

The semiconductor device according to any one of Appendixes 1 to 6, further including a carrier accumulation layer provided on the side of the first main surface of the drift layer.

### (Appendix 8)

The semiconductor device according to any one of Appendixes 1 to 7, wherein

the two-stage active dummy trench has a first upper oxide film covering the first upper electrode and a first lower oxide film covering the first lower electrode,

the two-stage active trench has a second upper oxide film covering the second upper electrode and a second lower oxide film covering the second lower electrode,

a film thickness of the first lower oxide film is thicker than a film thickness of the first upper oxide film, and

a film thickness of the second lower oxide film is thicker than a film thickness of the second upper oxide film.

### (Appendix 9)

The semiconductor device according to any one of Appendixes 1 to 8, wherein

a length of the first lower electrode in a depth direction is longer than a length of the first upper electrode in the depth direction, and

a length of the second lower electrode in the depth direction is longer than a length of the second upper electrode in the depth direction.

### (Appendix 10)

The semiconductor device according to any one of Appendixes 1 to 8, wherein

a length of the first lower electrode in a depth direction is shorter than a length of the first upper electrode in the depth direction, and

a length of the second lower electrode in the depth direction is shorter than a length of the second upper electrode in the depth direction.

### (Appendix 11)

The semiconductor device according to any one of Appendixes 1 to 10, wherein each of the first upper electrode and the second upper electrode has a first portion and a second portion each forming a shape recessed toward the first main surface.

### (Appendix 12)

The semiconductor device according to any one of Appendixes 1 to 11, wherein

two or more of the two-stage active dummy trenches are provided adjacent to each other, and

two or more of the two-stage active trenches are provided adjacent to each other.

### (Appendix 13)

The semiconductor device according to any one of Appendixes 1 to 12, further comprising a plurality of trench groups each including the two-stage active dummy trench and the two-stage active trench, wherein

each of the trench groups has a different ratio including the two-stage active trench.

### (Appendix 14)

The semiconductor device according to Appendix 13, wherein the trench group located on an inner side has a higher ratio including the two-stage active trench than the trench group located on an outer side in plan view.

### (Appendix 15)

The semiconductor device according to Appendix 13, wherein the trench group located on an inner side has a higher ratio including the two-stage active dummy trench than the trench group located on an outer side in plan view.

### (Appendix 16)

The semiconductor device according to any one of Appendixes 1 to 15, further comprising at least one one-stage dummy trench having a dummy electrode inside a trench provided on the side of the first main surface of the semiconductor substrate.

### (Appendix 17)

The semiconductor device according to Appendix 16, wherein a number of the one-stage dummy trenches is smaller than a number of the two-stage active dummy trenches.

### (Appendix 18)

The semiconductor device according to Appendix 16, wherein a number of the one-stage dummy trenches is smaller than a number of the two-stage active trenches.

### (Appendix 19)

The semiconductor device according to any one of Appendixes 1 to 7 or 9 to 18, wherein

the two-stage active dummy trench has a first upper oxide film covering the first upper electrode and a first lower oxide film covering the first lower electrode,

the two-stage active trench has a second upper oxide film covering the second upper electrode and a second lower oxide film covering the second lower electrode,

a film thickness of the first lower oxide film is thinner than a film thickness of the first upper oxide film, and

a film thickness of the second lower oxide film is thinner than a film thickness of the second upper oxide film.

### (Appendix 20)

The semiconductor device according to any one of Appendixes 1 to 19, further comprising:

a first resistor connected between the first upper electrode and the second upper electrode, and a gate electrode; and

a second resistor connected between the second lower electrode and the gate electrode, wherein

a resistance value of the first resistor is larger than a resistance value of the second resistor.

### (Appendix 21)

The semiconductor device according to any one of Appendixes 1 to 20, the semiconductor device being a reverse conducting-insulated gate bipolar transistor (RC-IGBT).

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate having a drift layer of a first conductivity type between a first main surface and a second main surface;
at least one two-stage active dummy trench having a first upper electrode as a gate potential in an upper stage and a first lower electrode as an emitter potential in a lower stage inside a trench provided on a side of the first main surface of the semiconductor substrate;
at least one two-stage active trench having a second upper electrode as the gate potential in an upper stage and a second lower electrode as the gate potential in a lower stage inside a trench provided on the side of the first main surface of the semiconductor substrate; and
a semiconductor layer of a second conductivity type provided on a side of the second main surface of the semiconductor substrate, wherein
the first upper electrode, the second upper electrode, and the second lower electrode are connected to an identical gate pad,
the two-stage active dummy trench and the two-stage active trench extend in a horizontal direction in plan view, and
a length of a region where the two-stage active dummy trench and the two-stage active trench are adjacent to each other is longer than a length of a region where the two-stage active dummy trench and the two-stage active trench are not adjacent to each other in an entire length of the two-stage active dummy trench and the two-stage active trench in the horizontal direction.

2. The semiconductor device according to claim 1, further comprising a base layer of the second conductivity type provided on the side of the first main surface of the semiconductor substrate, wherein
the two-stage active dummy trench has a first boundary oxide film located between the first upper electrode and the first lower electrode,
the two-stage active trench has a second boundary oxide film located between the second upper electrode and the second lower electrode, and
a protrusion width, which is a width between an end face of the base layer on the side of the second main surface and an end face of each of the first upper electrode and the second upper electrode on the side of the second main surface is longer than a film thickness of the first boundary oxide film and a film thickness of the second boundary oxide film.

3. The semiconductor device according to claim 1, further comprising a base layer of the second conductivity type provided on the side of the first main surface of the semiconductor substrate, wherein
a length between the two-stage active dummy trench and the two-stage active trench is shorter than a length between an end face of the base layer on the side of the second main surface and each of an end face of the two-stage active dummy trench on the side of the second main surface and an end face of the two-stage active trench on the side of the second main surface.

4. The semiconductor device according to claim 1, wherein a number of the two-stage active trenches is identical to a number of the two-stage active dummy trenches.

5. The semiconductor device according to claim 1, wherein a number of the two-stage active trenches is larger than a number of the two-stage active dummy trenches.

6. The semiconductor device according to claim 1, wherein a number of the two-stage active trenches is smaller than a number of the two-stage active dummy trenches.

7. The semiconductor device according to claim 1, further comprising a carrier accumulation layer provided on the side of the first main surface of the drift layer.

8. The semiconductor device according to claim 1, wherein
the two-stage active dummy trench has a first upper oxide film covering the first upper electrode and a first lower oxide film covering the first lower electrode,
the two-stage active trench has a second upper oxide film covering the second upper electrode and a second lower oxide film covering the second lower electrode,
a film thickness of the first lower oxide film is thicker than a film thickness of the first upper oxide film, and
a film thickness of the second lower oxide film is thicker than a film thickness of the second upper oxide film.

9. The semiconductor device according to claim 1, wherein
a length of the first lower electrode in a depth direction is longer than a length of the first upper electrode in the depth direction, and
a length of the second lower electrode in the depth direction is longer than a length of the second upper electrode in the depth direction.

10. The semiconductor device according to claim 1, wherein
a length of the first lower electrode in a depth direction is shorter than a length of the first upper electrode in the depth direction, and
a length of the second lower electrode in the depth direction is shorter than a length of the second upper electrode in the depth direction.

11. The semiconductor device according to claim 1, wherein each of the first upper electrode and the second upper electrode has a first portion and a second portion each forming a shape recessed toward the first main surface.

12. The semiconductor device according to claim 1, wherein
two or more of the two-stage active dummy trenches are provided adjacent to each other, and
two or more of the two-stage active trenches are provided adjacent to each other.

13. The semiconductor device according to claim 1, further comprising a plurality of trench groups each including the two-stage active dummy trench and the two-stage active trench, wherein
each of the trench groups has a different ratio including the two-stage active trench.

14. The semiconductor device according to claim 13, wherein the trench group located on an inner side has a higher ratio including the two-stage active trench than the trench group located on an outer side in plan view.

15. The semiconductor device according to claim 13, wherein the trench group located on an inner side has a higher ratio including the two-stage active dummy trench than the trench group located on an outer side in plan view.

16. The semiconductor device according to claim 1, further comprising at least one one-stage dummy trench having a dummy electrode inside a trench provided on the side of the first main surface of the semiconductor substrate.

17. The semiconductor device according to claim 16, wherein a number of the one-stage dummy trenches is smaller than a number of the two-stage active dummy trenches.

18. The semiconductor device according to claim 16, wherein a number of the one-stage dummy trenches is smaller than a number of the two-stage active trenches.

19. The semiconductor device according to claim 1, wherein
the two-stage active dummy trench has a first upper oxide film covering the first upper electrode and a first lower oxide film covering the first lower electrode,
the two-stage active trench has a second upper oxide film covering the second upper electrode and a second lower oxide film covering the second lower electrode,
a film thickness of the first lower oxide film is thinner than a film thickness of the first upper oxide film, and
a film thickness of the second lower oxide film is thinner than a film thickness of the second upper oxide film.

20. The semiconductor device according to claim 1, further comprising:
a first resistor connected between the first upper electrode and the second upper electrode, and a gate electrode; and
a second resistor connected between the second lower electrode and the gate electrode, wherein
a resistance value of the first resistor is larger than a resistance value of the second resistor.

21. The semiconductor device according claim 1, the semiconductor device being a reverse conducting-insulated gate bipolar transistor (RC-IGBT).
